(19) United States
(12) Patent Application Publication
(10) Pub. No.: US 2024/0096653 A1
(43) Pub. Date: Mar. 21, 2024

(54) SUBSTRATE TREATMENT APPARATUS AND METHOD FOR TREATING SUBSTRATE

(71) Applicants: SHIBAURA MECHATRONICS CORPORATION, Yokohama-shi (JP); KIOXIA CORPORATION, Tokyo (JP)

(72) Inventors: Kensuke DEMURA, Yokohama-shi (JP); Satoshi NAKAMURA, Yokohama-shi (JP); Masaya KAMIYA, Yokohama-shi (JP); Minami NAKAMURA, Yokohama-shi (JP); Kosuke TAKAI, Yokohama-shi (JP); Mana TANABE, Tokyo (JP); Kaori UMEZAWA, Fujisawa-shi (JP)

(21) Appl. No.: 18/469,619

(22) Filed: Sep. 19, 2023

(30) Foreign Application Priority Data
Sep. 21, 2022 (JP) 2022-149643

(51) Int. Cl. H01L 21/67; H01L 21/02; H01L 21/687

(52) U.S. Cl. CPC H01L 21/67051; H01L 21/02052; H01L 21/67023; H01L 21/67109; H01L 21/68764

(57) ABSTRACT

According to one embodiment a substrate treatment apparatus incorporates, into a frozen film, a contaminant adhered to a substrate surface by freezing a liquid film on the surface. The apparatus includes a placement part configured to rotate the substrate, a liquid supply part configured to supply a liquid via a nozzle to the frozen film including the contaminant, a moving part configured to move the nozzle parallel to the substrate surface, and a controller configured to control a rotation of the substrate by the placement part, a supply of the liquid by the liquid supply part, and a movement of the nozzle by the moving part. The controller rotates the substrate by controlling the placement part, supplies the liquid to the frozen film by controlling the liquid supply part, and moves the nozzle from a perimeter edge vicinity to a rotation center vicinity of the substrate by controlling the moving part.

### CROSS-REFERENCE TO RELATED APPLICATIONS

This application is based upon and claims the benefit of priority from the Japanese Patent Application No. 2022-149643, filed on Sep. 21, 2022; the entire contents of which are incorporated herein by reference.

### FIELD

Embodiments described herein relate generally to a substrate treatment apparatus and a method for treating a substrate.

### BACKGROUND

Freeze cleaning has been proposed to remove contaminants such as particles and the like from the surface of a substrate such as an imprint template, a photolithography mask, a semiconductor wafer, etc.

In general freeze cleaning, purified water is used as the liquid used in the cleaning. For example, in freeze cleaning, first, purified water and a cooling gas are supplied to the surface of a rotating substrate. Then, the supply of the purified water is stopped, and a water film is formed on the surface of the substrate while discharging a portion of the supplied purified water. The water film is frozen by the supplied cooling gas. When the water film freezes to form an ice film, contaminants such as particles and the like are detached from the surface of the substrate by being incorporated into the ice film. Then, the ice film is melted by supplying purified water to the ice film; and the contaminants are removed from the surface of the substrate together with the purified water.

The contaminant removal rate can be increased by performing freeze cleaning. In recent years, however, it is desirable to further improve the contaminant removal rate.

It was found by investigations by the inventors that contaminants incorporated into the ice film do not move easily when the ice film is melted by supplying purified water to the ice film. It is difficult to improve the contaminant removal rate when the contaminants incorporated into the ice film do not move easily.

It is therefore desirable to develop technology in which the contaminants that are incorporated into the ice film can be moved easily.

### BRIEF DESCRIPTION OF THE DRAWINGS

FIG. 1 is a schematic view illustrating a substrate treatment apparatus according to an embodiment;

FIG. 2 is a timing chart illustrating operations of the substrate treatment apparatus;

FIG. 3 is a graph illustrating the temperature change of a liquid supplied to a surface of a substrate;

FIG. 4 is a graph illustrating the relationship between the movement mode of a liquid nozzle and the contaminant movement ratio;

FIGS. 5A and 5B are schematic views of processes, illustrating a thawing process according to a comparative example 1;

FIGS. 6A and 6B are schematic views of processes, illustrating the thawing process according to the comparative example 1;

FIGS. 7A and 7B are schematic views of processes, illustrating a thawing process according to a comparative example 2;

FIGS. 8A and 8B are schematic views of processes, illustrating the thawing process according to the comparative example 2;

FIGS. 9A and 9B are schematic views of processes, illustrating a thawing process according to an embodiment; and

FIGS. 10A and 10B are schematic views of processes, illustrating the thawing process according to the embodiment.

### DETAILED DESCRIPTION

A substrate treatment apparatus incorporates, into a frozen film, a contaminant adhered to a substrate surface by freezing a liquid film on the surface. The apparatus includes a placement part configured to rotate the substrate, a liquid supply part configured to supply a liquid via a nozzle to the frozen film including the contaminant, a moving part configured to move the nozzle parallel to the substrate surface, and a controller configured to control a rotation of the substrate by the placement part, a supply of the liquid by the liquid supply part, and a movement of the nozzle by the moving part. The controller rotates the substrate by controlling the placement part, supplies the liquid to the frozen film by controlling the liquid supply part, and moves the nozzle from a perimeter edge vicinity to a rotation center vicinity of the substrate by controlling the moving part.

Exemplary embodiments will now be described with reference to the drawings. Similar components in the drawings are marked with like reference numerals.

### Substrate Treatment Apparatus

First, a substrate treatment apparatus 1 according to the embodiment will be illustrated.

A substrate 100 that is illustrated below can be, for example, a semiconductor wafer, an imprint template, a photolithography mask, a plate-shaped body used in a MEMS (Micro Electro Mechanical System), etc. The substrate 100 is not limited to the substrate 100 that is illustrated.

An uneven portion that is a pattern may be formed in the surface of the substrate 100, or an uneven portion may not be formed. The substrate 100 in which an uneven portion is not formed can be, for example, a so-called bulk substrate, etc.

The substrate treatment apparatus may supply a cooling gas to the front side of the substrate 100 (e.g., the side at which a liquid film described below is formed), may supply a cooling gas to the backside of the substrate 100 (e.g., the side opposite to the side at which the liquid film is formed), or may supply a cooling gas to the front side and backside of the substrate 100.

A substrate treatment apparatus that supplies a cooling gas to the backside of the substrate 100 will now be described as an example.

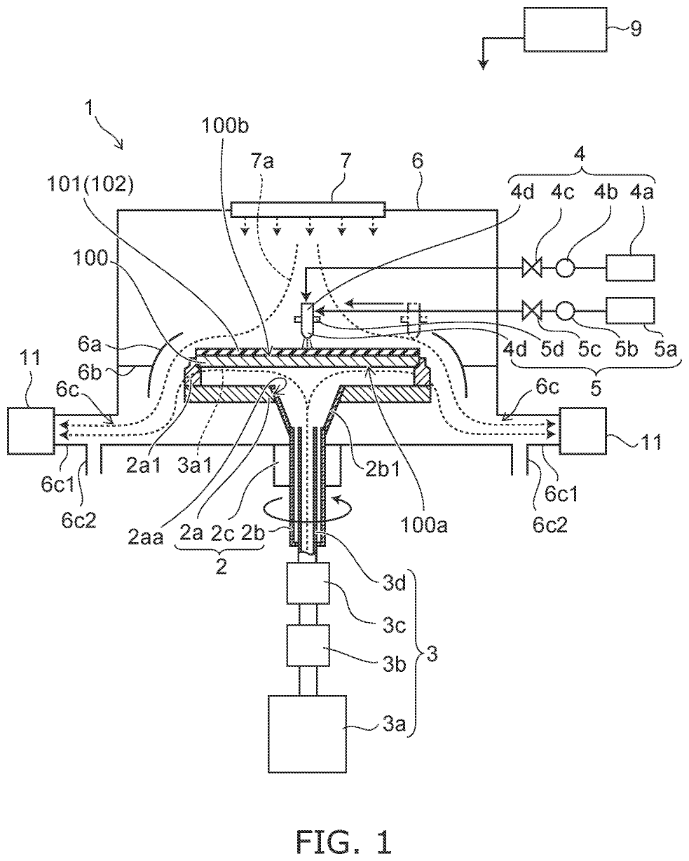

FIG. 1 is a schematic view illustrating the substrate treatment apparatus 1 according to the embodiment.

As shown in FIG. 1, the substrate treatment apparatus 1 includes, for example, a placement part 2, a cooling part 3, a first liquid supply part 4, a second liquid supply part 5, a chamber 6, a blower 7, a controller 9, and an exhaust part 11. FIG. 1 illustrates a case where the first liquid supply part 4 and the second liquid supply part 5 share a nozzle to discharge liquids.

The placement part 2 includes, for example, a placement platform 2a, a rotary shaft 2b, and a driver 2c.

The placement platform 2a is configured to rotate inside the chamber 6. The placement platform 2a is plate-shaped. Multiple supporters 2a1 that support the substrate 100 are located at one major surface of the placement platform 2a. When the substrate 100 is supported by the multiple supporters 2a1, a front surface 100b of the substrate 100 (the surface at the side to be cleaned) faces away from the placement platform 2a side.

A hole 2aa that extends through the placement platform 2a in the thickness direction is located at the central portion of the placement platform 2a.

One end portion of the rotary shaft 2b is located at the inner wall of the hole 2aa of the placement platform 2a. The other end portion of the rotary shaft 2b is located outside the chamber 6. The rotary shaft 2b is connected with the driver 2c outside the chamber 6.

The rotary shaft 2b is tubular. An outlet 2b1 is located at the end portion of the rotary shaft 2b at the placement platform 2a side. The outlet 2b1 is open at the surface of the placement platform 2a at which the multiple supporters 2a1 are located. The end portion of the outlet 2b1 at the opening side is connected to the inner wall of the hole 2aa. The opening of the outlet 2b1 faces a back surface 100a of the substrate 100 placed on the placement platform 2a. The cross-sectional area of the outlet 2b1 in directions orthogonal to the central axis of the rotary shaft 2b increases toward the placement platform 2a side (the opening side).

By providing the outlet 2b1, a cooling gas 3a1 that is released can be supplied to a wider region of the back surface 100a of the substrate 100. Also, the release rate of the cooling gas 3a1 can be reduced. Therefore, partial cooling of the substrate 100 and an excessively high cooling rate of the substrate 100 can be suppressed, and difficulties when generating a supercooled state of a liquid 101 described below can be suppressed.

A cooling nozzle 3d is mounted to the end portion of the rotary shaft 2b at the side opposite to the placement platform 2a side. A not-illustrated rotary shaft seal is located between the cooling nozzle 3d and the end portion of the rotary shaft 2b at the side opposite to the placement platform 2a side. Therefore, the end portion of the rotary shaft 2b at the side opposite to the placement platform 2a side is airtightly sealed.

The driver 2c is located outside the chamber 6. The driver 2c is connected with the rotary shaft 2b. The rotational force of the driver 2c is transferred to the placement platform 2a via the rotary shaft 2b. Therefore, the placement platform 2a as well as the substrate 100 placed on the placement platform 2a can be rotated by the driver 2c.

The driver 2c not only can start and stop the rotation but also can change the rotational speed (the speed of rotation). The driver 2c can include, for example, a control motor such as a servo motor, etc.

The cooling part 3 supplies the cooling gas 3a1 to the space between the placement platform 2a and the back surface 100a of the substrate 100. The cooling part 3 includes, for example, a cooling liquid part 3a, a filter 3b, a flow rate controller 3c, and the cooling nozzle 3d. The cooling liquid part 3a, the filter 3b, and the flow rate controller 3c are located outside the chamber 6.

The cooling liquid part 3a stores a cooling liquid and generates the cooling gas 3a1. The cooling liquid is the liquefied cooling gas 3a1. The cooling gas 3a1 is not particularly limited as long as the cooling gas 3a1 is a gas that does not easily react with the material of the substrate 100. The cooling gas 3a1 can be, for example, an inert gas such as nitrogen gas, helium gas, argon gas, etc.

The cooling liquid part 3a includes a tank that stores the cooling liquid, and a vaporizer that vaporizes the cooling liquid stored in the tank. A cooling device for maintaining the temperature of the cooling liquid is located in the tank. The vaporizer generates the cooling gas 3a1 from the cooling liquid by increasing the temperature of the cooling liquid. For example, the vaporizer can utilize the outside air temperature or can use heat from a heating medium. It is sufficient for the temperature of the cooling gas 3a1 to be not more than the freezing point of the liquid 101; for example, the temperature of the cooling gas 3a1 can be −170° C.

The cooling gas 3a1 also can be generated by using a chiller or the like to cool an inert gas such as nitrogen gas, etc. Thus, the cooling liquid part can be simplified.

The filter 3b is connected to the cooling liquid part 3a via a pipe. The filter 3b suppresses the outflow toward the substrate 100 side of contaminants such as particles, etc., included in the cooling liquid.

The flow rate controller 3c is connected to the filter 3b via a pipe. The flow rate controller 3c controls the flow rate of the cooling gas 3a1. The flow rate controller 3c can be, for example, a MFC (Mass Flow Controller), etc. The flow rate controller 3c may indirectly control the flow rate of the cooling gas 3a1 by controlling the supply pressure of the cooling gas 3a1. In such a case, the flow rate controller 3c can be, for example, an APC (Auto Pressure Controller), etc.

The temperature of the cooling gas 3a1 generated from the cooling liquid in the cooling liquid part 3a is a substantially prescribed temperature. Therefore, the flow rate controller 3c can control the temperature of the substrate 100 as well as the temperature of the liquid 101 at the front surface 100b of the substrate 100 by controlling the flow rate of the cooling gas 3a1. In such a case, the liquid 101 can be set to a supercooled state in a cooling process described below by the flow rate controller 3c controlling the flow rate of the cooling gas 3a1.

The cooling nozzle 3d is tubular. One end portion of the cooling nozzle 3d is connected to the flow rate controller 3c. The other end portion of the cooling nozzle 3d is located inside the rotary shaft 2b. The other end portion of the cooling nozzle 3d is positioned at the vicinity of the end portion of the outlet 2b1 at the side opposite to the placement platform 2a side (the opening side).

The cooling gas 3a1 of which the flow rate is controlled by the flow rate controller 3c is supplied to the substrate 100 by the cooling nozzle 3d. The cooling gas 3a1 that is released from the cooling nozzle 3d is directly supplied to the back surface 100a of the substrate 100 via the outlet 2b1.

As described above, the substrate treatment apparatus may supply the cooling gas 3a1 to the front surface 100b side of the substrate 100, or may supply the cooling gas 3a1 to the front surface 100b side and the back surface 100a side of the substrate 100. When the cooling gas 3a1 is supplied to the front surface 100b side of the substrate 100, it is sufficient to provide the cooling nozzle 3d at the front surface 100b side of the substrate 100.

When, however, the cooling gas 3a1 is supplied to the front surface 100b side of the substrate 100, the freezing starts from the surface of the liquid film formed at the front surface 100b of the substrate 100. When the freezing starts from the surface of the liquid film, the contaminants that are adhered to the front surface 100b of the substrate 100 are not easily detached from the front surface 100b of the substrate 100.

Therefore, to improve the contaminant removal rate, it is favorable for the substrate treatment apparatus 1 to supply the cooling gas 3a1 to the back surface 100a side of the substrate 100.

The first liquid supply part 4 supplies the liquid 101 to the front surface 100b of the substrate 100. The liquid 101 is not particularly limited as long as the liquid 101 does not easily react with the material of the substrate 100. For example, the liquid 101 can be water (e.g., purified water, ultrapure water, etc.), a liquid that includes water as a major component, a liquid in which gas is dissolved, etc.

In a freezing process (solid-liquid phase) described below, there are cases where a contaminant is the starting point of the freezing of the liquid 101 (the starting point when changing to a solid). For example, starting points of the freezing of the liquid 101 in the supercooled state include a density change due to the temperature nonuniformity of the liquid film, the existence of contaminants such as particles or the like, vibrations, etc. That is, contaminants form some percentage of the starting points of the freezing.

The mechanism of the contaminants detaching from the front surface 100b of the substrate 100 can be considered to be as follows. For example, when volume expansion of the liquid 101 occurs when freezing, forces are applied to the contaminants at the starting points of the freezing in directions away from the front surface 100b of the substrate 100. A pressure wave is generated when the volume of the liquid 101 changes when freezing. It is considered that the contaminants adhered to the front surface 100b of the substrate 100 are detached by the pressure wave.

The first liquid supply part 4 includes, for example, a liquid container 4a, a supply part 4b, a flow rate controller 4c, and a liquid nozzle 4d. The liquid container 4a, the supply part 4b, and the flow rate controller 4c are located outside the chamber 6.

The liquid container 4a stores the liquid 101. The liquid container 4a stores the liquid 101 at a higher temperature than the freezing point. The temperature of the liquid 101 stored in the liquid container 4a is, for example, room temperature (e.g., 20° C.).

The supply part 4b is connected to the liquid container 4a via a pipe. The supply part 4b supplies the liquid 101 stored in the liquid container 4a toward the liquid nozzle 4d. The supply part 4b can be, for example, a pump that is resistant to the liquid 101, etc.

The flow rate controller 4c is connected to the supply part 4b via a pipe. The flow rate controller 4c controls the flow rate of the liquid 101 supplied by the supply part 4b. The flow rate controller 4c can be, for example, a flow rate control valve. The flow rate controller 4c can start and stop the supply of the liquid 101.

The liquid nozzle 4d is located inside the chamber 6. The liquid nozzle 4d is tubular. One end portion of the liquid nozzle 4d is connected to the flow rate controller 4c via a pipe. The other end portion of the liquid nozzle 4d faces the front surface 100b of the substrate 100 placed on the placement platform 2a. The liquid 101 that is discharged from the liquid nozzle 4d is supplied to the front surface 100b of the substrate 100.

The other end portion of the liquid nozzle 4d (the discharge port of the liquid 101) is located at the position of the rotation center of the substrate 100 when forming the liquid film described below. In other words, the liquid 101 is supplied to substantially the center of the front surface 100b of the substrate 100. The liquid 101 that is supplied to substantially the center of the front surface 100b of the substrate 100 spreads to the perimeter edge vicinity of the front surface 100b of the substrate 100 and forms a liquid film having a substantially constant thickness on the front surface 100b of the substrate 100. In the specification, the film of the liquid 101 formed at the front surface 100b of the substrate 100 is called the liquid film.

The second liquid supply part 5 supplies a liquid 102 to the front surface 100b of the substrate 100.

The liquid 102 is used in a thawing process described below. It is therefore sufficient that the liquid 102 does not easily react with the material of the substrate 100 and does not easily remain at the front surface 100b of the substrate 100 in a drying process described below. Similarly to the liquid 101 described above, the liquid 102 can be, for example, water (e.g., purified water, ultrapure water, etc.), a liquid including water as a major component, a liquid in which gas is dissolved, etc. In such a case, the liquid 102 may be the same as or different from the liquid 101.

The second liquid supply part 5 includes, for example, a liquid container 5a, a supply part 5b, a flow rate controller 5c, the liquid nozzle 4d, and a moving part 5d.

The liquid container 5a can be similar to the liquid container 4a described above. The supply part 5b can be similar to the supply part 4b described above. The flow rate controller 5c can be similar to the flow rate controller 4c described above.

Although FIG. 1 illustrates a case where the liquid nozzle 4d is used to supply both the liquid 101 used to form the liquid film and the liquid 102 used in the thawing, a liquid nozzle that supplies the liquid 101 and a liquid nozzle that supplies the liquid 102 can be provided separately. A case will now be described where the liquid nozzle 4d is used for both.

The moving part 5d can be used when supplying the liquid 102 used in the thawing. The moving part 5d moves the position of the liquid nozzle 4d in a direction parallel to the front surface 100b of the substrate 100. The moving part 5d includes, for example, an arm that holds the liquid nozzle 4d, and a motor that turns the arm. The moving part 5d also may include, for example, a holder that holds the liquid nozzle 4d, and a guide and motor that move the holder linearly. The movement speed of the liquid nozzle 4d can be changed by using a control motor such as a servo motor or the like as the motor.

As described above, the liquid 102 can be the same as the liquid 101. When the liquid 102 is the same as the liquid 101, the second liquid supply part 5 can be omitted. When the second liquid supply part 5 is omitted, the first liquid supply part 4 is used in the thawing process as well. That is, the liquid 101 is used in the thawing process as well. As described below, the position of the liquid nozzle 4d is moved in the thawing process. Therefore, when the second liquid supply part 5 is omitted, the moving part 5d is provided in the first liquid supply part 4.

The temperature of the liquid 102 can be higher than the freezing point of the liquid 101. For example, it is sufficient for the temperature of the liquid 102 to be a temperature at which the frozen liquid 101 can be thawed. The temperature of the liquid 102 is, for example, about room temperature (e.g., 20° C.). The thawing time can be reduced by setting the temperature of the liquid 102 to be greater than room temperature. When the temperature of the liquid 102 is set to be greater than room temperature, for example, a heater and a temperature control device are included in the liquid container 5a.

In the thawing process as well, when the liquid 101 is used and the temperature of the liquid 101 is set to be greater than room temperature, the temperature of the liquid film formed before a cooling process described below is high. When the temperature of the liquid film is high, the duration of the cooling process increases. Therefore, when the temperature of the liquid used in the thawing process is set to be greater than room temperature, it is favorable to include the second liquid supply part 5 even when the liquid 102 is the same as the liquid 101.

The chamber 6 is box-shaped. A cover 6a is located inside the chamber 6. The cover 6a catches the liquids 101 and 102 that are supplied to the substrate 100 and are discharged outward of the substrate 100 by the rotation of the substrate 100. A divider 6b is located inside the chamber 6. The divider 6b is located between the outer surface of the cover 6a and the inner surface of the chamber 6.

Multiple outlets 6c are provided in the side surface of the chamber 6 at the bottom surface side. The cooling gas 3a1, the liquid 101, and the liquid 102 after use, and air 7a supplied by the blower 7 are discharged outside the chamber 6 from the outlet 6c. An exhaust pipe 6c1 is connected to the outlet 6c; and the exhaust part 11 such as a pump or the like that exhausts the used cooling gas 3a1 and the air 7a is connected to the exhaust pipe 6c1. A discharge pipe 6c2 that discharges the liquids 101 and 102 also is connected to the outlet 6c.

The blower 7 is located at the ceiling surface of the chamber 6. As long as the blower 7 is at the ceiling side, the blower 7 can be located at the side surface of the chamber 6. The blower 7 includes, for example, a filter and a circulator such as a fan, etc. The filter is, for example, a HEPA filter (High Efficiency Particulate Air Filter), etc.

The controller 9 controls the operations of the components included in the substrate treatment apparatus 1. The controller 9 includes, for example, a calculation part such as a CPU (Central Processing Unit) or the like, a storage part such as semiconductor memory, etc. The controller 9 is, for example, a computer. A control program that controls the operations of the components included in the substrate treatment apparatus 1 is stored in the storage part. The calculation part sequentially performs a preliminary process, a formation process of the liquid film, a cooling process, a thawing process, and a drying process described below based on the control program stored in the storage part.

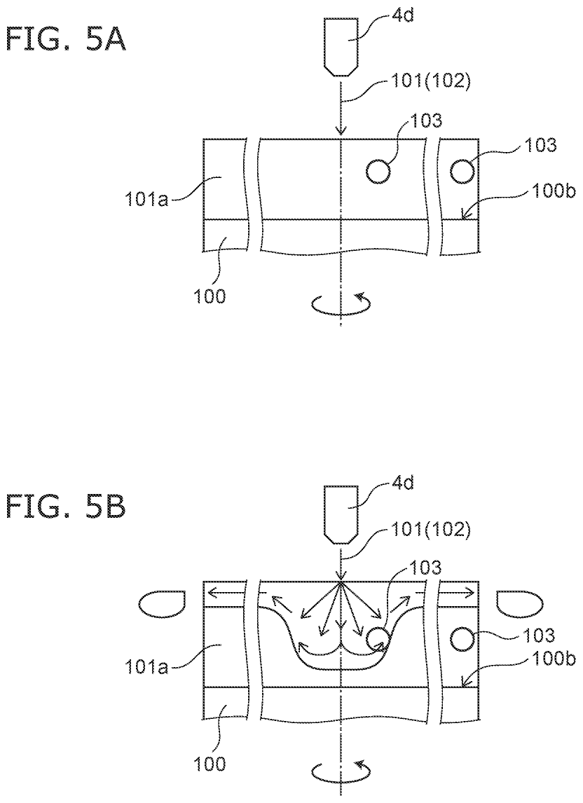

As described above, the substrate treatment apparatus 1 according to the embodiment forms a frozen film 101a by freezing a liquid film formed at the front surface 100b of the substrate 100, and incorporates, into the frozen film 101a, contaminants 103 adhered to the front surface 100b of the substrate 100 (see FIG. 5A).

The substrate treatment apparatus 1 includes the placement part 2 that is configured to rotate the substrate 100, a liquid supply part that includes the liquid nozzle 4d and is configured to supply the liquid 101 (102) via the liquid nozzle 4d to the frozen film 101a including the contaminants 103, the moving part 5d that is configured to move the position of the liquid nozzle 4d in a direction parallel to the front surface 100b of the substrate 100, and the controller 9 that is configured to control the rotation of the substrate 100 by the placement part 2, the supply of the liquid 101 (102) by the liquid supply part, and the movement of the liquid nozzle 4d by the moving part 5d.

The controller 9 rotates the substrate 100 by controlling the placement part 2, supplies the liquid 101 (102) to the frozen film 101a by controlling the liquid supply part, and moves the liquid nozzle 4d from the perimeter edge vicinity of the substrate 100 to the rotation center vicinity of the substrate 100 by controlling the moving part 5d.

Operations of the substrate treatment apparatus 1 will now be described further.

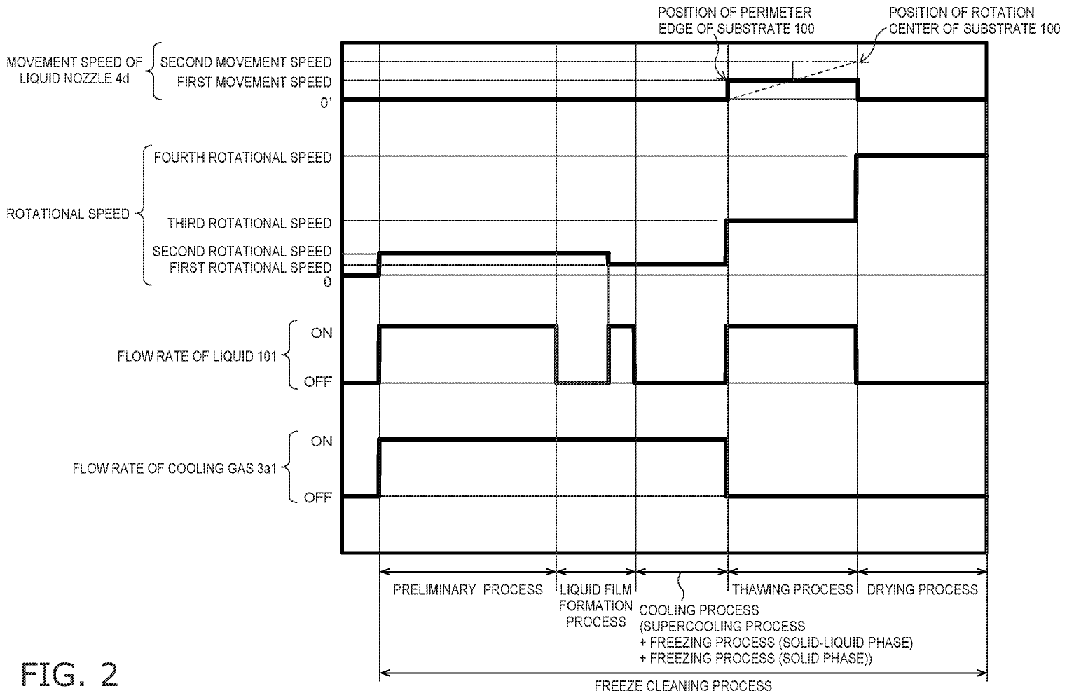

FIG. 2 is a timing chart illustrating operations of the substrate treatment apparatus 1.

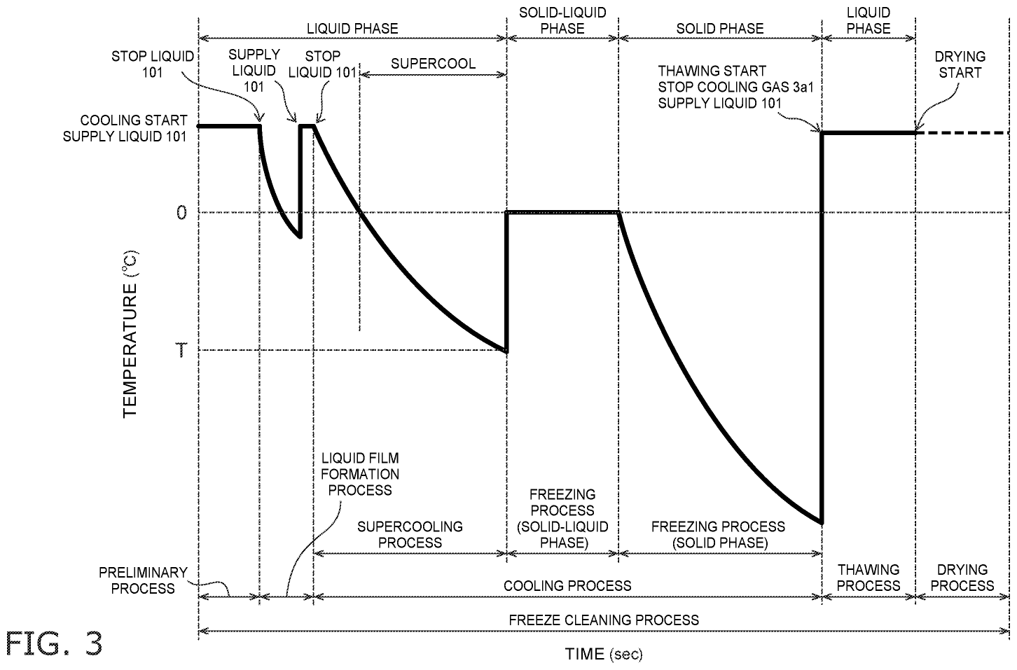

FIG. 3 is a graph illustrating the temperature change of the liquid 101 supplied to the front surface 100b of the substrate 100.

FIGS. 2 and 3 illustrate a case where the substrate 100 is a 6025 quartz (Qz) substrate (152 mm×152 mm×6.35 mm), and the liquids 101 and 102 are purified water.

The liquid 102 that is used in the thawing is the same as the liquid 101 that is used to form the liquid film. Therefore, in FIGS. 2 and 3, the liquid 101 is used in the thawing process as well.

First, the substrate 100 is transferred into the chamber 6 via a not-illustrated receive/dispatch port of the chamber 6. The transferred substrate 100 is placed on and supported by the multiple supporters 2a1 of the placement platform 2a.

After the substrate 100 is supported by the placement platform 2a, the freeze cleaning process that includes the preliminary process, the formation process of the liquid film, the cooling process, the thawing process, and the drying process is performed as shown in FIGS. 2 and 3.

First, the preliminary process is performed as shown in FIGS. 2 and 3.

In the preliminary process, the controller 9 supplies a prescribed flow rate of the liquid 101 to the front surface 100b of the substrate 100 by controlling the supply part 4b and the flow rate controller 4c. Also, the controller 9 supplies a prescribed flow rate of the cooling gas 3a1 to the back surface 100a of the substrate 100 by controlling the flow rate controller 3c. The controller 9 also rotates the substrate 100 at a second rotational speed by controlling the driver 2c.

Here, when the atmosphere inside the chamber 6 is cooled by supplying the cooling gas 3a1, there is a risk that frost that includes dust from the atmosphere may adhere to the substrate 100 and cause contamination. Therefore, the liquid 101 is continuously supplied to the front surface 100b of the substrate 100 in the preliminary process. In other words, in the preliminary process, frost is prevented from adhering to the front surface 100b of the substrate 100 while the substrate 100 is being cooled.

The second rotational speed is, for example, about 50 rpm to 500 rpm. The flow rate of the liquid 101 is, for example, about 0.1 L/min to 1.0 L/min. The flow rate of the cooling gas 3a1 is, for example, about 40 NL/min to 200 NL/min. The process time of the preliminary process is about 1800 seconds.

In the preliminary process, the temperature of the liquid film is substantially equal to the temperature of the liquid 101 being supplied because the liquid 101 is supplied continuously. For example, the temperature of the liquid film is about room temperature (20° C.) when the temperature of the liquid 101 being supplied is about room temperature (20° C.).

Then, the formation process of the liquid film is performed as shown in FIGS. 2 and 3.

In the formation process of the liquid film, the supply of the liquid 101 of the preliminary process is stopped. The liquid 101 that is at the front surface 100b of the substrate 100 is discharged because the rotation of the substrate 100 is maintained. At this time, the rotational speed of the substrate 100 is reduced to a first rotational speed at which fluctuation of the thickness of the liquid film due to the centrifugal force can be suppressed. The first rotational speed is, for example, 0 rpm to 50 rpm.

After the rotational speed of the substrate 100 is set to the first rotational speed, a liquid film is formed by supplying a prescribed amount of the liquid 101 to the substrate 100. The thickness of the liquid film (the thickness of the liquid film when performing the cooling process) is, for example, about 300 μm to 1300 μm.

The flow rate of the cooling gas 3a1 during the formation process of the liquid film is maintained at the same flow rate as the preliminary process. The in-plane temperature of the substrate 100 is substantially uniform in the preliminary process described above. In the formation process of the liquid film, the state in which the in-plane temperature of the substrate 100 is substantially uniform can be maintained by maintaining the flow rate of the cooling gas 3a1 at the same flow rate as the preliminary process.

Then, the cooling process is performed as shown in FIGS. 2 and 3.

In the specification, the cooling process includes a “supercooling process”, a “freezing process (solid-liquid phase)”, and a “freezing process (solid phase)”. The “supercooling process” is a process in which the liquid 101 reaches a supercooled state until the liquid 101 in the supercooled state starts to freeze. In the supercooling process, only the liquid 101 exists over the entire front surface 100b of the substrate 100. The “freezing process (solid-liquid phase)” is a process in which the freezing of the liquid 101 in the supercooled state starts until the freezing completely finishes. In the freezing process (solid-liquid phase), the liquid 101 and the frozen liquid 101 exist over the entire front surface 100b of the substrate 100. The “freezing process (solid phase)” is a process after the liquid 101 has completely frozen. In the freezing process (solid phase), only the frozen liquid 101 exists over the entire front surface 100b of the substrate 100. The liquid film that is completely frozen is called the frozen film 101a.

There are also cases where the thawing process is performed before forming the frozen film 101a by performing the freezing process (solid-liquid phase) after the formation process of the liquid film without performing the supercooling process. There are also cases where the freezing process (solid-liquid phase) and the freezing process (solid phase) are sequentially performed after the formation process of the liquid film without performing the supercooling process. In other words, there are cases where the supercooling process and the freezing process (solid phase) are omitted. Even when the supercooling process and the freezing process (solid phase) are omitted, the contaminants 103 can be detached from the front surface 100b of the substrate 100. By omitting the supercooling process and the freezing process (solid phase), the cooling process can be simplified, and the duration of the cooling process can be reduced. As described below, stress is generated in the frozen film 101a when the freezing process (solid phase) is performed. When fine uneven portions exist in the front surface 100b of the substrate 100, there is a risk that the uneven portions may be damaged by the generated stress. In such a case, the damage of the uneven portions can be suppressed by omitting the freezing process (solid phase).

However, by performing the supercooling process and the freezing process (solid phase) as described below, the contaminants 103 can be efficiently detached from the front surface 100b of the substrate 100. In recent years, it is desirable to improve the removal rate of the contaminants 103. Therefore, in the specification, the case is described where the supercooling process, the freezing process (solid-liquid phase), and the freezing process (solid phase) are sequentially performed.

In the supercooling process, the temperature of the liquid film on the substrate 100 drops below the temperature of the liquid film of the formation process of the liquid film due to the cooling gas 3a1 continuously supplied to the back surface 100a of the substrate 100; and the liquid film reaches a supercooled state. In such a case, when the cooling rate of the liquid 101 is too high, the liquid 101 may quickly freeze without reaching the supercooled state. Therefore, the controller 9 causes the liquid 101 of the front surface 100b of the substrate 100 to reach the supercooled state by controlling at least one of the rotational speed of the substrate 100, the flow rate of the cooling gas 3a1, or the flow rate of the liquid 101.

The control conditions at which the liquid 101 reaches the supercooled state are affected by the size of the substrate 100, the viscosity of the liquid 101, the specific heat of the cooling gas 3a1, etc. It is therefore favorable to appropriately determine the control conditions at which the liquid 101 reaches the supercooled state by performing experiments and/or simulations.

As described above, there are also cases where the supercooling process is not performed. In such a case, the controller 9 increases the cooling rates of the liquid 101 by controlling at least one of the rotational speed of the substrate 100, the flow rate of the cooling gas 3a1, or the flow rate of the liquid 101. As a result, the freezing process (solid-liquid phase) is performed without performing the supercooling process.

When the liquid 101 in the supercooled state starts to freeze, the supercooling process transitions to the freezing process (solid-liquid phase). In the supercooled state, for example, the freezing of the liquid 101 starts in response to the temperature of the liquid film, the existence of bubbles, contaminants such as particles, vibrations, etc. For example, when contaminants such as particles or the like exist, the freezing of the liquid 101 starts when a temperature T of the liquid 101 is not less than −35° C. and not more than −20° C. Also, the freezing of the liquid 101 can be started by applying a vibration to the liquid 101 by causing the rotation of the substrate 100 to fluctuate, etc.

As described above, in the liquid 101 in the supercooled state, contaminants form some percentage of the starting points of the freezing. The contaminants that are the starting points of the freezing are incorporated into the frozen film 101a. Therefore, the contaminant removal rate can be improved by performing the supercooling process. It is considered that the contaminants adhered to the front surface 100b of the substrate 100 are detached by the pressure wave accompanying the volume change when the liquid 101 changes to a solid, the physical force accompanying the volume increase, etc.

Then, the thawing process is performed as shown in FIGS. 2 and 3.

For example, the start of the thawing process can be determined based on the elapsed time from the start timing of the preliminary process and/or the start timing of the freezing process (solid-liquid phase). However, this is an example, and the timing of the thawing start also can be determined based on the change of the surface state of the liquid 101 (the frozen film 101a) of the front surface 100b of the substrate 100 by detecting the surface state by using a detecting part, etc.

The thawing process is described below in detail.

Then, the drying process is performed as shown in FIGS. 2 and 3.

In the drying process, the controller 9 stops the supply of the liquid 101 by controlling the supply part 4b and the flow rate controller 4c. When the liquid 101 and the liquid 102 are different liquids, the controller 9 stops the supply of the liquid 102 by controlling the supply part 5b and the flow rate controller 5c.

The controller 9 sets the rotational speed of the substrate 100 to a fourth rotational speed that is faster than the rotational speed of the substrate 100 in the thawing process (a third rotational speed described below) by controlling the driver 2c. The drying time of the substrate 100 can be reduced by making the rotation of the substrate 100 faster. The fourth rotational speed is not particularly limited as long as drying can be performed.

Thus, the freeze cleaning process ends. The freeze cleaning process can be performed multiple times.

The substrate 100 for which the freeze cleaning has ended is dispatched out of the chamber 6 via a not-illustrated receive/dispatch port of the chamber 6.

The thawing process will now be described further.

In the thawing process, the controller 9 supplies the liquid 101 to the frozen film 101a by controlling the supply part 4b and the flow rate controller 4c. When the liquid 101 and the liquid 102 are different, the controller 9 supplies the liquid 102 to the frozen film 101a by controlling the supply part 5b and the flow rate controller 5c.

At this time, as shown in FIG. 2, the controller 9 moves the liquid nozzle 4d over the front surface 100b of the substrate 100 from a position of the perimeter edge of the substrate 100 to the rotation center of the substrate 100 by controlling the moving part 5d.

As described above, the controller 9 can control the moving part 5d so that the movement speed of the liquid nozzle 4d is constant, or so that the movement speed of the liquid nozzle 4d changes as shown by the single dot-dash line in FIG. 2.

In such a case, as shown in FIG. 2, the controller 9 can control the moving part 5d so that a second movement speed of the liquid nozzle 4d at the rotation center vicinity of the substrate 100 is faster than a first movement speed of the liquid nozzle 4d at the perimeter edge vicinity of the substrate 100. For example, the second movement speed can be about 2 times the first movement speed.

As shown in FIG. 2, the controller 9 can control the moving part 5d so that the movement speed of the liquid nozzle 4d gradually increases, or so that the movement speed of the liquid nozzle 4d increases in stages.

Thus, the duration of the liquid nozzle 4d moving over the frozen film 101a at the perimeter edge vicinity of the substrate 100 is greater than the duration of the liquid nozzle 4d moving over the frozen film 101a at the rotation center vicinity of the substrate 100. Therefore, the frozen film 101a can be reliably thawed at the perimeter edge vicinity of the substrate 100 by increasing the duration of the supply of the liquid 101 and the thawing at the perimeter edge vicinity at which the surface area of the frozen film 101a is greater than the surface area of the frozen film 101a at the rotation center vicinity of the substrate 100.

The appropriate value of the movement speed of the liquid nozzle 4d, the appropriate values of the variable speed conditions of the movement speed, etc., are affected by the thickness of the frozen film 101a, the temperature of the frozen film 101a, the speed of rotation of the substrate 100, the temperature and/or flow rate of the liquid 101 (102) used in the thawing, etc. It is therefore favorable to appropriately determine the movement speed of the liquid nozzle 4d, the variable speed conditions of the movement speed, etc., by performing experiments and/or simulations.

The flow rate of the liquid 101 or 102 is not particularly limited as long as thawing can be performed. The temperature of the liquid 101 or 102 can be room temperature (e.g., 20° C.). As described above, the temperature of the liquid 101 used in the formation of the liquid film can be set to room temperature (e.g., 20° C.), and the temperature of the liquid 102 used in the thawing can be set to a temperature that is greater than room temperature.

When the liquid nozzle 4d moves to the rotation center of the substrate 100 and the thawing process is finished, the controller 9 stops the supply of the cooling gas 3a1 by controlling the flow rate controller 3c. Also, the controller 9 increases the rotational speed of the substrate 100 from the first rotational speed to the third rotational speed by controlling the driver 2c. The third rotational speed is, for example, about 200 rpm to 700 rpm. By making the rotation of the substrate 100 faster, the liquid 101 and the frozen liquid 101 can be flung off by the centrifugal force. Therefore, the liquid 101 and the frozen liquid 101 are easily discharged from the front surface 100b of the substrate 100. At this time, the contaminants 103 that are detached from the front surface 100b of the substrate 100 are discharged together with the liquid 101 and the frozen liquid 101.

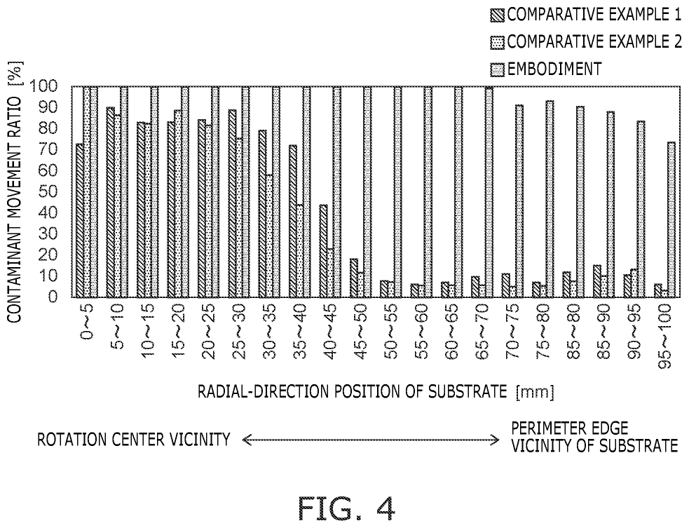

FIG. 4 is a graph illustrating the relationship between the movement mode of the liquid nozzle 4d and the movement ratio of the contaminants 103.

The movement mode of the liquid nozzle 4d according to the comparative example 1 is a case where the liquid 101 (102) is supplied to the frozen film 101a from above the front surface 100b of the substrate 100 at the position of the rotation center of the substrate 100. In such a case, the liquid nozzle 4d is not moved from the position of the rotation center of the substrate 100.

The movement mode of the liquid nozzle 4d according to a comparative example 2 is a case where the liquid 101 (102) is supplied to the frozen film 101a from above the front surface 100b of the substrate 100 from the position of the rotation center of the substrate 100. In such a case, the liquid nozzle 4d is moved from the position of the rotation center of the substrate 100 toward the perimeter edge of the substrate 100.

The movement mode of the liquid nozzle 4d according to the embodiment is a case where the liquid 101 (102) is supplied to the frozen film 101a from above the front surface 100b of the substrate 100 from a position at the vicinity of the perimeter edge of the substrate 100. In such a case, the liquid nozzle 4d is moved from the position at the vicinity of the perimeter edge of the substrate 100 toward the rotation center of the substrate 100.

The movement ratio of the contaminants 103 refers to the ratio of contaminants before thawing that were moved after thawing. A high movement ratio of the contaminants 103 means that the removal rate of the contaminants 103 is high.

It can be seen from FIG. 4 that in the entire region of the substrate 100, the movement ratio of the contaminants 103 of the movement mode of the liquid nozzle 4d according to the embodiment can be drastically increased compared to the movement modes of the liquid nozzle 4d according to the comparative examples 1 and 2. For the movement modes of the liquid nozzle 4d according to the comparative examples 1 and 2, the movement ratio of the contaminants 103 at the perimeter edge vicinity of the substrate 100 was low, whereas the movement ratio of the contaminants 103 at the perimeter edge vicinity of the substrate 100 was high for the movement mode of the liquid nozzle 4d according to the embodiment.

In other words, according to the movement mode of the liquid nozzle 4d according to the embodiment, the removal rate of the contaminants 103 can be improved over the entire region of the substrate 100.

As described below, the behavior of the contaminants 103 when the frozen film 101a is thawed also is different when the movement mode of the liquid nozzle 4d is different.

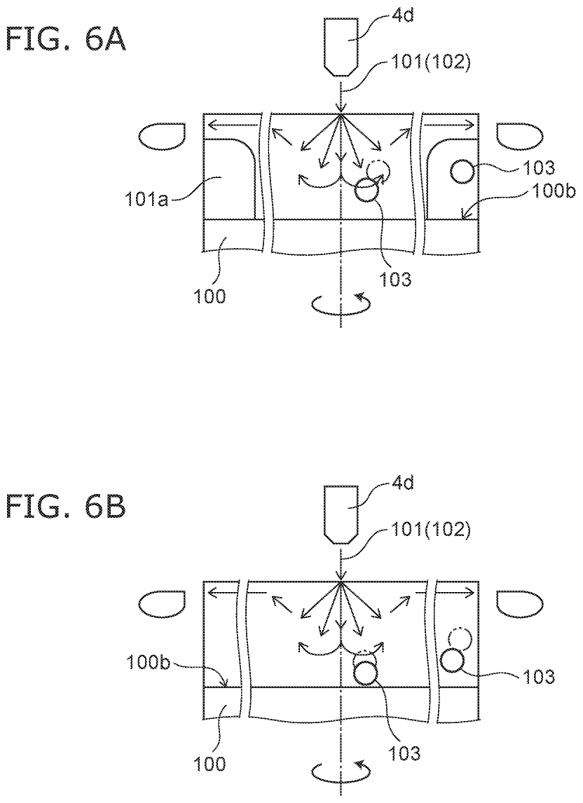

FIGS. 5A to 6B are schematic views of processes, illustrating the thawing process according to the comparative example 1.

First, as shown in FIG. 5A, the liquid 101 (102) is supplied to the frozen film 101a at the position of the rotation center of the substrate 100.

As shown in FIG. 5B, the frozen film 101a is melted by the liquid 101 (102) at the vicinity of the rotation center of the substrate 100.

As the thawing proceeds as shown in FIGS. 6A and 6B, the thawed portion of the frozen film 101a spreads outward from the position of the rotation center of the substrate 100. When the frozen film 101a remains at the perimeter edge vicinity of the substrate 100 as shown in FIG. 6A, the liquid 101 (102) that is supplied strikes the end portion of the frozen film 101a at the rotation center vicinity. In such a case, a portion of the liquid 101 (102) is discharged outside the substrate 100 by passing over the end portion of the frozen film 101a. The remaining a portion of the liquid 101 (102) strikes the end portion of the frozen film 101a and is thereby returned to the rotation center vicinity of the substrate 100.

The contaminants 103 that are incorporated into the frozen film 101a can be discharged if the contaminants 103 are carried by the flow of the liquid 101 (102) discharged outside the substrate 100.

If, however, the contaminants 103 are carried by the flow of the liquid 101 (102) returning to the rotation center vicinity of the substrate 100 as shown in FIGS. 6A and 6B, the contaminants 103 move to the front surface 100b vicinity of the substrate 100.

In other words, the movement ratio of the contaminants 103 is low when the liquid 101 (102) is simply supplied to the frozen film 101a at the position of the rotation center of the substrate 100.

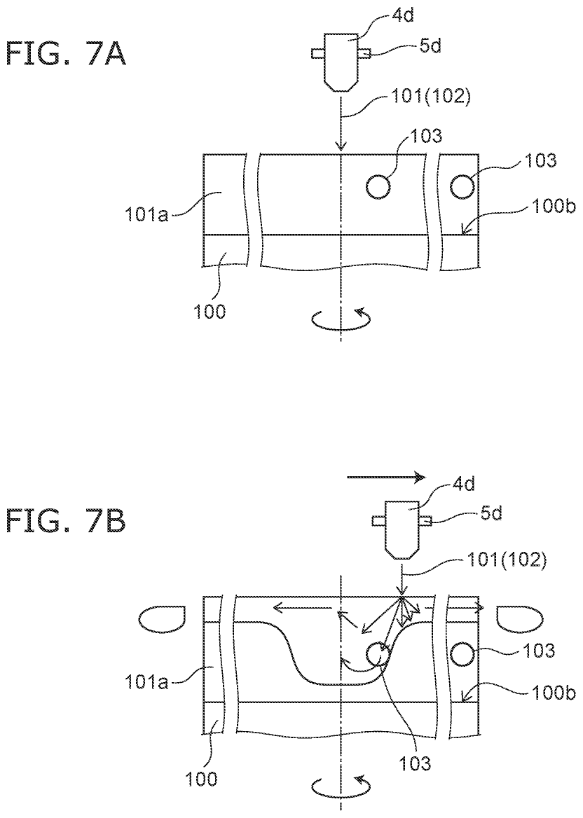

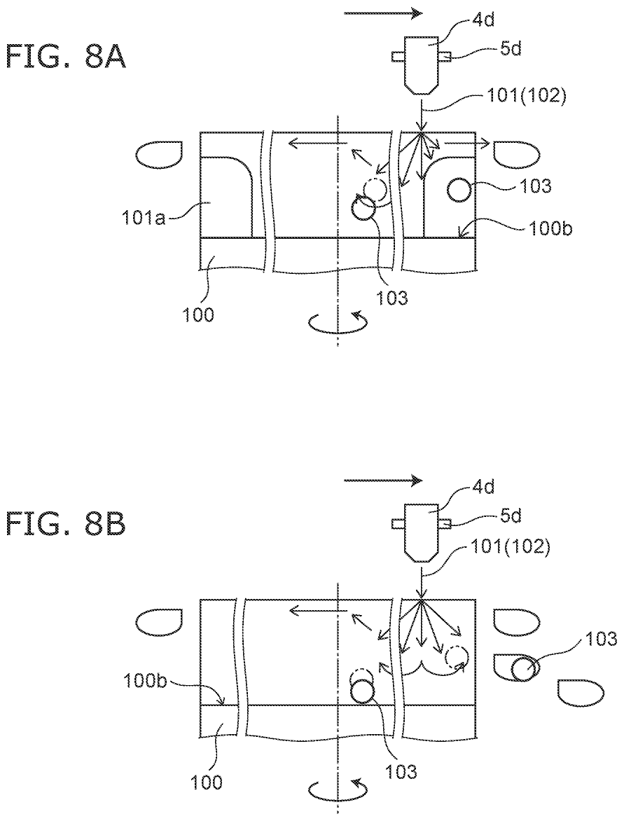

FIGS. 7A to 8B are schematic views of processes, illustrating the thawing process according to the comparative example 2.

First, as shown in FIG. 7A, the liquid 101 (102) is supplied to the frozen film 101a at the position of the rotation center of the substrate 100.

As shown in FIG. 7B, the frozen film 101a is melted by the liquid 101 (102) at the vicinity of the rotation center of the substrate 100.

The controller 9 moves the liquid nozzle 4d from the position of the rotation center of the substrate 100 toward the perimeter edge of the substrate 100 by controlling the moving part 5d. In such a case, the liquid nozzle 4d is moved in a direction parallel to the front surface 100b of the substrate 100.

Therefore, as shown in FIG. 7B, the frozen film 101a thaws outward from the position of the rotation center of the substrate 100.

As the thawing proceeds as shown in FIGS. 7B and 8A, the thawed portion of the frozen film 101a spreads outward from the position of the rotation center of the substrate 100. In such a case, the liquid nozzle 4d is positioned at the vicinity of the end portion of the frozen film 101a at the rotation center vicinity because the liquid nozzle 4d moves toward the perimeter edge of the substrate 100.

Therefore, as shown in FIGS. 7B and 8A, a portion of the liquid 101 (102) supplied from the liquid nozzle 4d flows more easily toward the front surface 100b vicinity of the substrate 100 along the end portion of the frozen film 101a at the rotation center vicinity. The liquid 101 (102) that flows over the surface of the frozen film 101a is discharged outside the substrate 100. The contaminants 103 that are incorporated into the frozen film 101a can be discharged if the contaminants 103 are carried by the flow of the liquid 101 (102) discharged outside the substrate 100.

If, however, the contaminants 103 are carried by the flow of the liquid 101 (102) flowing toward the front surface 100b vicinity of the substrate 100, the contaminants 103 move to the front surface 100b vicinity of the substrate 100.

In other words, the movement ratio of the contaminants 103 is low even when the liquid nozzle 4d is moved from the position of the rotation center of the substrate 100 toward the perimeter edge of the substrate 100.

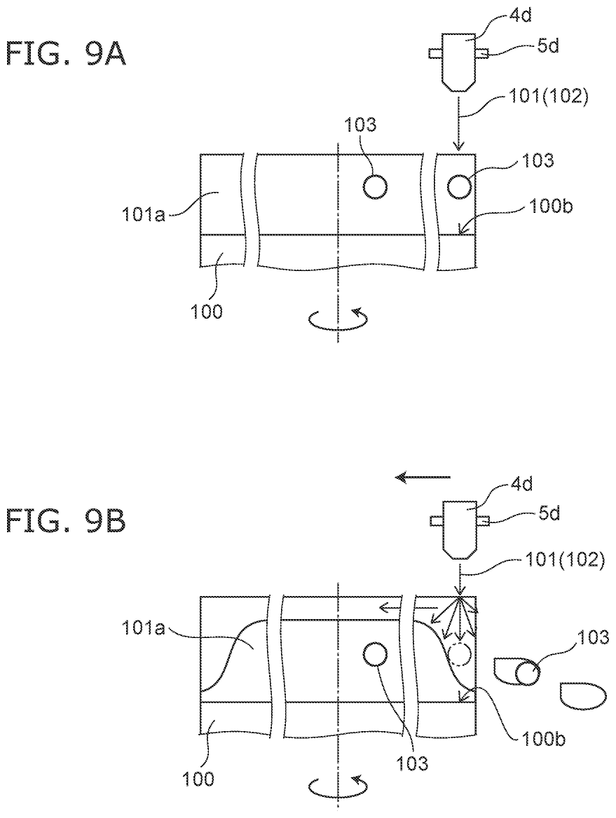

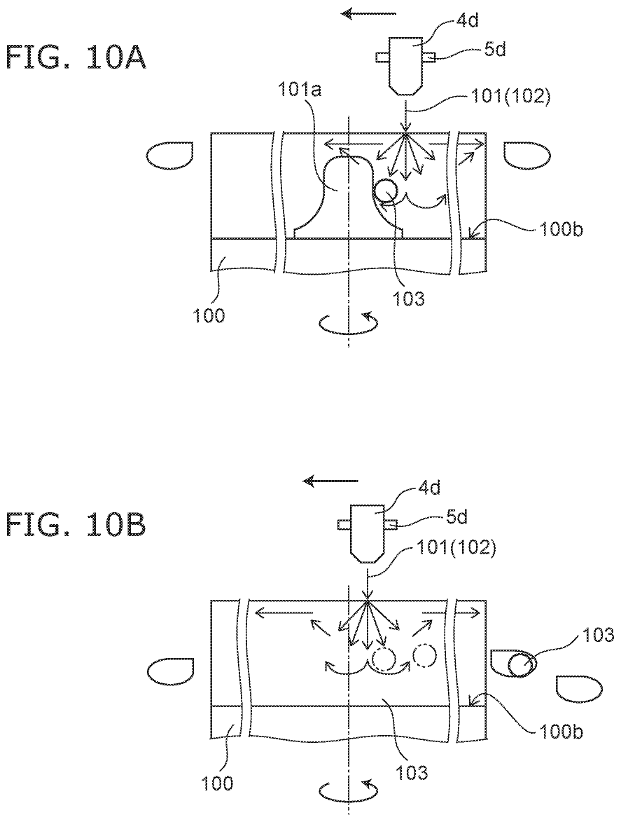

FIGS. 9A to 10B are schematic views of processes, illustrating the thawing process according to the embodiment.

First, as shown in FIG. 9A, the liquid 101 (102) is supplied to the frozen film 101a at the position at the vicinity of the perimeter edge of the substrate 100. As shown in FIG. 9B, the frozen film 101a is melted by the liquid 101 (102) at the vicinity of the perimeter edge of the substrate 100.

The liquid 101 (102) that is used in the thawing and the liquid 101 that is generated by the frozen film 101a thawing are discharged outside the substrate 100 by the centrifugal force. Therefore, as shown in FIG. 9B, the contaminants 103 that are incorporated into the frozen film 101a at the perimeter edge vicinity of the substrate 100 are easily discharged outside the substrate 100.

The controller 9 moves the liquid nozzle 4d from the position of the perimeter edge of the substrate 100 toward the position of the rotation center of the substrate 100 by controlling the moving part 5d. In such a case, the liquid nozzle 4d is moved in a direction parallel to the front surface 100b of the substrate 100.

Therefore, as the thawing proceeds as shown in FIGS. 10A and 10B, the thawed portion of the frozen film 101a spreads from the position of the perimeter edge of the substrate 100 toward the position of the rotation center of the substrate 100.

Because the liquid nozzle 4d moves toward the position of the rotation center of the substrate 100, the liquid nozzle 4d is positioned at the vicinity of the end portion of the frozen film 101a at the perimeter edge vicinity as shown in FIG. 10A.

Therefore, as shown in FIG. 10A, a portion of the liquid 101 (102) supplied from the liquid nozzle 4d strikes the end portion of the frozen film 101a at the perimeter edge vicinity and flows more easily toward the perimeter edge vicinity of the substrate 100. The frozen film 101a at the perimeter edge vicinity of the substrate 100 thaws. Therefore, the liquid 101 (102) that is used in the thawing and the liquid 101 that is generated by the frozen film 101a thawing are discharged outside the substrate 100 as-is by the centrifugal force without being shielded by the frozen film 101a.

The contaminants 103 that are incorporated into the frozen film 101a can be smoothly discharged because the contaminants 103 are carried by the flow of the liquid 101 (102) discharged outside the substrate 100.

In other words, the movement ratio of the contaminants 103 can be increased by moving the liquid nozzle 4d from the perimeter edge vicinity of the substrate 100 toward the rotation center vicinity of the substrate 100.

In the thawing process according to the embodiment as described above, the frozen film 101a that is formed at the front surface 100b of the substrate 100 is sequentially thawed from the perimeter edge vicinity toward the rotation center vicinity of the substrate 100. It can be seen from FIG. 4 that thawing the frozen film 101a from the perimeter edge vicinity of the substrate 100 can move the contaminants 103 adhered over the entire region of the front surface 100b of the substrate 100. Also, if the frozen film 101a at the perimeter edge vicinity of the substrate 100 is thawed, the liquid 101 (102) that is used in the thawing and the liquid 101 that is generated by the frozen film 101a thawing are discharged as-is outside the substrate 100 by the centrifugal force without being shielded by the frozen film 101a. Therefore, the movement ratio of the contaminants 103 can be increased, and the contaminant removal rate can be improved.

By performing the supercooling process and the freezing process (solid phase) as described above, more contaminants 103 are incorporated into the frozen film 101a. According to the thawing process according to the embodiment, the movement ratio of the contaminants 103 can be increased even when more contaminants 103 are incorporated into the frozen film 101a. Therefore, the removal rate of the contaminants 103 can be further improved by performing the supercooling process, the freezing process (solid phase), and the thawing process according to the embodiment.

The liquid 101 (102) that is used in the thawing can be a mixed liquid of water and an alkaline solution. Thus, the contaminants 103 that are incorporated into the frozen film 101a are moved more easily because the zeta potential of the liquid 101 (102) used in the thawing can be reduced.

The liquid 101 (102) that is used in the thawing can be a mixed liquid of water and an acid solution. Thus, the contaminants 103 that include an organic substance (e.g., resist residue, etc.) and are incorporated into the frozen film 101a can be melted.

### Method for Treating Substrate

A method for treating a substrate according to the embodiment will now be described.

For example, the method for treating the substrate according to the embodiment can be performed using the substrate treatment apparatus 1 described above.

The method for treating the substrate can include, for example, the following processes:
a process of incorporating, into a frozen film, the contaminants 103 adhered to the front surface 100b of the substrate 100 by forming the frozen film by freezing a liquid film formed at the front surface 100b of the substrate 100; and
a process of thawing the frozen film by rotating the substrate 100 and supplying the liquid 101 (102) via the liquid nozzle 4d to the frozen film including the contaminants 103.

The process of thawing the frozen film includes moving the position of the liquid nozzle 4d from a perimeter edge vicinity of the substrate 100 to a rotation center vicinity of the substrate 100 in a direction parallel to the front surface 100b of the substrate 100.

In the process of thawing the frozen film, the movement speed of the liquid nozzle 4d can be set to a constant, or the movement speed of the liquid nozzle 4d can be changed.

In the process of thawing the frozen film, the movement speed of the liquid nozzle 4d at the rotation center vicinity of the substrate 100 can be set to be faster than the movement speed of the liquid nozzle 4d at the perimeter edge vicinity of the substrate 100.

In the process of thawing the frozen film, the movement speed of the liquid nozzle 4d can be gradually increased, or the movement speed of the liquid nozzle 4d can be increased in stages.

The content of the processes can be similar to the content according to the substrate treatment apparatus 1 described above, and a detailed description is therefore omitted.

While certain embodiments have been described, these embodiments have been presented by way of example only, and are not intended to limit the scope of the inventions. Indeed, the novel embodiments described herein may be embodied in a variety of other forms; furthermore, various omissions, substitutions, and changes in the form of the embodiments herein may be made without departing from the spirit of the inventions. The accompanying claims and their equivalents are intended to cover such forms or modifications as would fall within the scope and spirit of the inventions. Moreover, above-mentioned embodiments can be combined mutually and can be carried out.

What is claimed is:

1. A substrate treatment apparatus incorporating, into a frozen film, a contaminant adhered to a surface of a substrate by forming the frozen film by freezing a liquid film formed at the surface of the substrate, the apparatus comprising:
a placement part configured to rotate the substrate;
a liquid supply part including a nozzle, the liquid supply part being configured to supply a liquid via the nozzle to the frozen film including the contaminant;
a moving part configured to move a position of the nozzle in a direction parallel to the surface of the substrate; and
a controller configured to control a rotation of the substrate by the placement part, a supply of the liquid by the liquid supply part, and a movement of the nozzle by the moving part,
the controller
rotating the substrate by controlling the placement part,
supplying the liquid to the frozen film by controlling the liquid supply part, and
moving the nozzle from a perimeter edge vicinity of the substrate to a rotation center vicinity of the substrate by controlling the moving part.

2. The apparatus according to claim 1, wherein
by controlling the moving part, the controller sets a movement speed of the nozzle to be constant, or changes the movement speed of the nozzle.

3. The apparatus according to claim 1, wherein
by controlling the moving part, the controller sets a movement speed of the nozzle at the rotation center vicinity of the substrate to be faster than the movement speed of the nozzle at the perimeter edge vicinity of the substrate.

4. The apparatus according to claim 3, wherein
the movement speed of the nozzle at the rotation center vicinity of the substrate is 2 times the movement speed of the nozzle at the perimeter edge vicinity of the substrate.

5. The apparatus according to claim 3, wherein
by controlling the moving part, the controller gradually increases the movement speed of the nozzle, or increases the movement speed of the nozzle in stages.

6. The apparatus according to claim 3, wherein
a duration of the movement of the nozzle over the frozen film at the perimeter edge vicinity of the substrate is greater than a duration of the movement of the nozzle over the frozen film at the rotation center vicinity of the substrate.

7. The apparatus according to claim 1, wherein
by controlling the moving part, the controller sequentially thaws the frozen film from the perimeter edge vicinity of the substrate toward the rotation center vicinity of the substrate by moving the nozzle from the perimeter edge vicinity of the substrate to the rotation center vicinity of the substrate.

8. The apparatus according to claim 7, wherein
the sequential thawing of the frozen film from the perimeter edge vicinity of the substrate toward the rotation center vicinity of the substrate causes the liquid supplied from the nozzle and a liquid generated by the thawing of the frozen film to be discharged outside the substrate without being shielded by the frozen film.

9. The apparatus according to claim 8, wherein
the liquid supplied from the nozzle and the liquid generated by the thawing of the frozen film are discharged outside the substrate by a centrifugal force.

10. The apparatus according to claim 1, wherein
by controlling the moving part, the controller moves the nozzle from a position of a perimeter edge of the substrate to a rotation center of the substrate.

11. A method for treating a substrate, the method comprising:
incorporating, into a frozen film, a contaminant adhered to a surface of a substrate by forming the frozen film by freezing a liquid film formed at the surface of the substrate; and
thawing the frozen film by rotating the substrate and by supplying a liquid via a nozzle to the frozen film including the contaminant,
the thawing of the frozen film including moving a position of the nozzle in a direction parallel to the surface of the substrate from a perimeter edge vicinity of the substrate to a rotation center vicinity of the substrate.

12. The method according to claim 11, wherein
the thawing of the frozen film includes setting a movement speed of the nozzle to be constant, or changing the movement speed of the nozzle.

13. The method according to claim 11, wherein
the thawing of the frozen film includes setting the movement speed of the nozzle at the rotation center vicinity of the substrate to be faster than the movement speed of the nozzle at the perimeter edge vicinity of the substrate.

14. The method according to claim 13, wherein
the movement speed of the nozzle at the rotation center vicinity of the substrate is 2 times the movement speed of the nozzle at the perimeter edge vicinity of the substrate in the thawing of the frozen film.

15. The method according to claim 13, wherein
the thawing of the frozen film includes gradually increasing the movement speed of the nozzle, or increasing the movement speed of the nozzle in stages.

16. The method according to claim 13, wherein
in the thawing of the frozen film, a duration of the movement of the nozzle over the frozen film at the perimeter edge vicinity of the substrate is greater than a duration of the movement of the nozzle over the frozen film at the rotation center vicinity of the substrate.

17. The method according to claim 11, wherein
the thawing of the frozen film includes sequentially thawing the frozen film from the perimeter edge vicinity of the substrate toward the rotation center vicinity of the substrate by moving the nozzle from the perimeter edge vicinity of the substrate to the rotation center vicinity of the substrate.

18. The method according to claim 17, wherein
in the thawing of the frozen film, the sequential thawing of the frozen film from the perimeter edge vicinity of the substrate toward the rotation center vicinity of the substrate causes the liquid supplied from the nozzle and a liquid generated by the thawing of the frozen film to be discharged outside the substrate without being shielded by the frozen film.

19. The method according to claim 18, wherein
the thawing of the frozen film includes using a centrifugal force to discharge, outside the substrate, the liquid supplied from the nozzle and the liquid generated by the thawing of the frozen film.

20. The method according to claim 11, wherein
the thawing of the frozen film includes moving the nozzle from a position of a perimeter edge of the substrate to a rotation center of the substrate.
